(19) United States
(12) Patent Application Publication
(10) Pub. No.: US 2002/0027399 A1
(43) Pub. Date: Mar. 7, 2002

(54) Driving apparatus and method for same

(76) Inventor: Hiroji Katsuragi, Osaka (JP)

Correspondence Address: Kevin R. Spivak, Morrison & Foerster LLP, Suite 5500, 2000 Pennsylvania Avenue, N.W., Washington, DC, 20006-1888, US

(21) Appl. No.: 09/925,974

(22) Filed: Aug. 10, 2001

(30) Foreign Application Priority Data
Aug. 18, 2000 (JP) 2000-248603

(51) Int. Cl. H01L 41/04

(52) U.S. Cl. 310/328; 310/317; 310/316.01

(57) ABSTRACT

A driving apparatus that does not include a member between the piezoelectric element and the target object. The driving apparatus comprises a piezoelectric element, which is fixed to a stationary member via the ends, a target object, which is frictionally engaged with the ends of the piezoelectric element, and piezoelectric element driving devices that each apply a voltage to the piezoelectric element such that the speed of extension and the speed of contraction of the portion of the piezoelectric element between the respective are different.

### RELATED APPLICATIONS

This application is based on application No. JP2000-248603 filed in Japan, the contents of which is hereby incorporated by reference.

### FIELD OF THE INVENTION

The present invention relates to an improved driving apparatus, and in particular, to a driving apparatus that drives a target object using a piezoelectric element. The present invention further relates to a driving apparatus that is appropriate for driving of a moving unit that is included inside a precision device, information recording device or the like, in particular.

### BACKGROUND OF THE INVENTION

Several types of driving apparatus using a piezoelectric element have conventionally been proposed. For example, the driving apparatus shown in FIG. 1 has the following construction. The piezoelectric element 4 is fixed to the base member 2 via one end of the extendable length thereof, while being connected via the other end to the driving shaft 6. The target object 7 is guided by the guide shaft 5 that is located parallel to the driving shaft 6, and the driving shaft 6 is frictionally engaged with the target object 7. When the driving shaft 6 is oscillated along its axis through the application of a sawtooth voltage to the piezoelectric element 4, for example, such that the speed of extension of the piezoelectric element 4 is different from the speed of contraction, the target object 7 moves along the driving shaft 6 (see, for example, U.S. Pat. No. 2,633,066).

However, because the type of driving apparatus described above requires a driving shaft 6 between the piezoelectric element 4 and the target object 7, there are limits to the extent to which it may be improved by making it smaller, thinner or less expensive.

### SUMMARY OF THE INVENTION

In one embodiment of the invention, there is a driving apparatus. The driving apparatus includes, for example, a base frame; an electro-mechanical transducer one end of which is fixed to the base frame; a moving member frictionally coupled with the electro-mechanical transducer; and a driver to drive the electro-mechanical transducer. The driver applies a voltage such that the speed of extension of the electro-mechanical transducer between the ends thereof differs from the speed of contraction.

In one aspect of the invention, the electro-mechanical transducer has a thin plate configuration.

In another aspect of the invention, the driver applies a voltage such that the speed of extension and contraction of the electro-mechanical transducer in the direction perpendicular to polarization are different.

In yet another aspect of the invention, the electro-mechanical transducer has a protrusion frictionally contacted with the moving member.

In still another aspect of the invention, the protrusion area is plated by material to prevent wearing of the electro-mechanical transducer.

In one aspect of the invention the driver applies a voltage in the thickness direction of the thin plate.

In another aspect of the invention, the electro-mechanical transducer has a disk configuration and a notch.

In yet another aspect of the invention, the electro-mechanical transducer has a disk configuration and a protrusion frictionally contacted with the moving member, the moving member driven to rotate by applying the voltage.

In still another aspect of the invention, the electro-mechanical transducer has a notch near the protrusion.

In yet another aspect of the invention, the electro-mechanical transducer is a piezoelectric element.

In still another aspect of the invention, the driving apparatus includes, for example, two groups of active electrodes on the thin plate, wherein the driver applies a voltage such that a first section of the thin plate, covered by the first electrode, extends at a high speed and contracts slowly while the second section of the thin plate, covered by the second electrode, contracts at a high speed and extends slowly.

In one aspect of the invention, the electro-mechanical transducer has a disk configuration and a notch.

In another aspect of the invention, four electrodes are allocated such that surface of disk is equally divided into parts by the four electrodes, such that electrodes of diagonal position make a pair.

In another embodiment of the invention, a driving apparatus includes, for example, a base frame; an electro-mechanical transducer one end of which is fixed to the base frame, the electro-mechanical transducer has a disk configuration and a contact part; a moving member frictionally contacted with a contact part of the electro-mechanical transducer, the moving member driven to rotate by applying a voltage; and a driver to drive the electro-mechanical transducer, wherein the driver applies the voltage such that a speed of extension of the electro-mechanical transducer between the ends thereof differs from the speed of contraction.

In one aspect of the invention, the electro-mechanical transducer has a notch near the contact part.

In another aspect of the invention, the driving apparatus includes two groups of active electrodes on a thin plate, wherein the driver applies a voltage such that a first section of the thin plate, covered by the first electrode, extends at a high speed and contracts slowly while the second section of the thin plate, covered by the second electrode, contracts at a high speed and extends slowly.

In yet another aspect of the invention, four electrodes are allocated such that surface of disk is equally divided into parts by the four electrodes, such that electrodes of diagonal position make a pair.

In still another aspect of the invention, the driver applies a voltage such that speeds of extension and contraction of the electro-mechanical transducer in the direction perpendicular to polarization are different.

In one aspect of the invention, the contact part is plated by material to prevent wearing of the electro-mechanical transducer.

In still another embodiment of the invention, the driving apparatus includes, for example, a base frame; an electro-mechanical transducer one end of which is fixed to the base frame, the electro-mechanical transducer has a thin plate configuration and a contact part; a moving member frictionally contacted with the contact part of the electro-mechanical transducer; and a driver to drive the electro-mechanical transducer, wherein the driver applies a voltage such that a speed of extension of the electro-mechanical transducer between the ends thereof differs from the speed of contraction.

In one aspect of the invention, the driving apparatus includes two groups of active electrodes on a thin plate, wherein the driver applies a voltage such that a first section of the thin plate, covered by the first electrode, extends at a high speed and contracts slowly while the second section of the thin plate, covered by the second electrode, contracts at a high speed and extends slowly.

In another aspect of the invention, the driver applies a voltage such that speeds of extension and contraction of the electro-mechanical transducer in the direction perpendicular to polarization are different.

In yet another aspect of the invention, the contact part is plated by material to prevent wearing of the electro-mechanical transducer.

In yet another embodiment of the invention, there is a method of driving an electro-mechanical transducer having two sections covered by two active electrodes. The method includes, for example, applying a voltage such that a first section of the electro-mechanical transducer extends at a high speed while a second section of the electro-mechanical transducer contracts slowly; and applying the voltage such that the first section of the electro-mechanical transducer contracts slowly while the second section of the electro-mechanical transducer extends at a high speed.

In one aspect of the invention, the electro-mechanical transducer has a disk configuration, and a moving member is driven to rotate by applying the voltage.

### BRIEF DESCRIPTION OF THE DRAWINGS

These and other objects and features of the present invention will become apparent from the following description of preferred embodiments thereof taken in conjunction with the accompanying drawings, in which:

FIG. 1 is a perspective view of a conventional driving apparatus.

FIG. 2 is a perspective view showing in a disassembled fashion the components of the driving apparatus of a first embodiment of the present invention.

FIG. 3 is a waveform diagram of the voltage applied between the electrodes shown in FIG. 2.

FIG. 4 is a cross-sectional view of the driving apparatus of a second embodiment of the present invention.

FIG. 5 is a waveform diagram of the voltage applied between the electrodes shown in FIG. 4.

FIG. 6 is a plan view of the driving unit cut along the line VI-VI in FIG. 4.

FIG. 7 shows a variation of the driving apparatus shown in FIG. 4.

FIG. 8 is a perspective view showing in a disassembled fashion the components of the driving apparatus of a third embodiment of the present invention.

FIG. 9 is a plan view of the driving unit shown in FIG. 8.

FIG. 10 is a perspective view in a disassembled fashion of the entire driving apparatus shown in FIG. 8.

FIG. 11 is a drawing illustrating components of a variation of the invention.

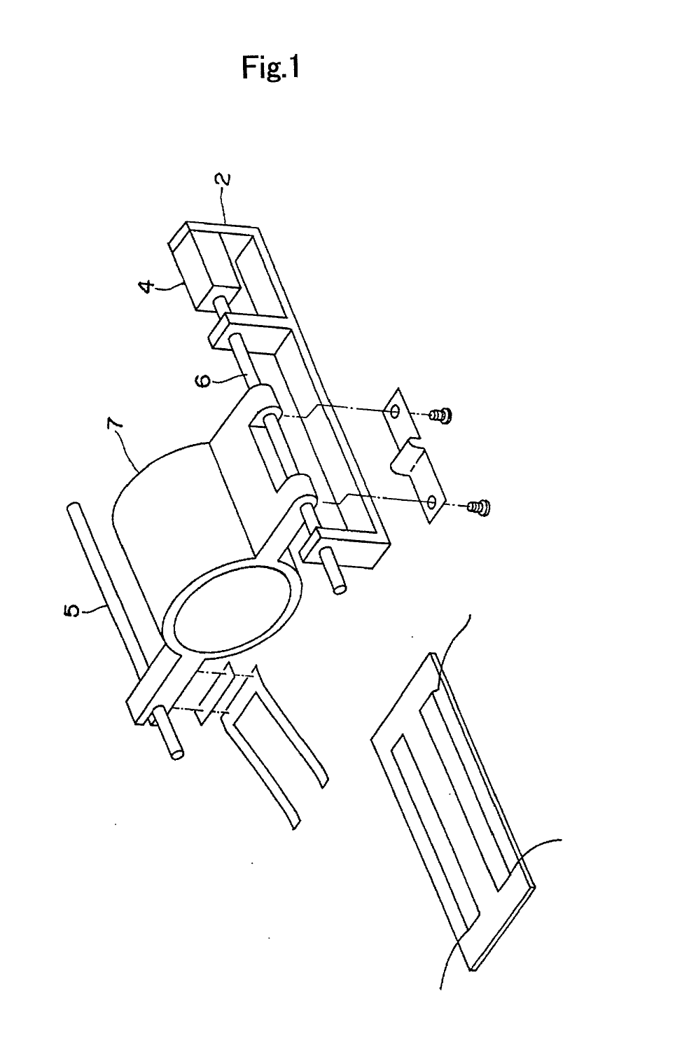

In the following description, like parts are designated by like reference numbers throughout the several drawings.

### DETAILED DESCRIPTION OF THE PREFERRED EMBODIMENTS

The present invention provides a driving apparatus that does not include a member between the piezoelectric element and the target object. More specifically, the present invention provides an improved driving apparatus that drives the target object using a piezoelectric element.

The driving apparatus, according to one embodiment, includes a piezoelectric element that is fixed via one end thereof to a static member, a target object that is frictionally engaged with the other end of the piezoelectric element, and a piezoelectric element driving device that applies a voltage such that the speed of extension of the piezoelectric element between the ends thereof differs from the speed of contraction.

Using the above construction, the application of a voltage to the piezoelectric element causes the piezoelectric element to extend and contract such that the distance between the two ends changes. Because one end of the piezoelectric element is fixed to a static member, the other end may move. When a voltage is applied to the piezoelectric element such that the speed of extension is different from the speed of contraction, the speed at which the other end of the piezoelectric element moves in one direction may be made different from the speed at which it moves in the opposite direction. Consequently, the target object that is frictionally engaged with the other end of the piezoelectric element may be moved in the direction in which the other end of the piezoelectric element moves relatively slowly.

Using the above construction, the target object may be driven directly by the piezoelectric element. In other words, there are no driving members between the piezoelectric element and the target object. As a result, the driving apparatus may be made smaller and thinner and its cost reduced.

According to another embodiment of the present invention, the driving apparatus has multiple piezoelectric elements.

Using the above construction, the target object is frictionally engaged with the multiple piezoelectric elements at multiple locations, such that it may be driven via these multiple locations. Therefore, this construction is appropriate for ensuring stable driving, high output and a smaller size of the driving apparatus.

According to another embodiment of the present invention, the piezoelectric element driving device applies a voltage such that the speeds of extension and contraction of the piezoelectric element in the direction perpendicular to polarization are different.

In this case, the piezoelectric element may be extended and contracted using the transverse effect (the distortion in the direction perpendicular to the electric field) of the piezoelectric material, for example.

According to another aspect of the present invention, the piezoelectric element has a thin plate configuration.

In this case, because the piezoelectric element may be placed in the small space between the static member and the target object, or electrodes may be formed along the surface of the piezoelectric element, this construction is appropriate for reducing the size of the driving apparatus.

Further, according to another embodiment of the present invention, the target object is located such that it may rotate on the static member. The piezoelectric element is placed between the target object and the static member. The portion between the two ends of the piezoelectric element extends in the direction of the diameter of the rotational shaft of the target object.

In the above construction, because the piezoelectric element is placed between the target object and the static member, one side of the piezoelectric element may be fixed to the static member while the other side thereof is frictionally engaged with the target object.

Using the above construction, because the other end of the piezoelectric element moves along its circumference, a driving force in the circumferential direction may be supplied to the target object and the target object may be driven to rotate. This construction is appropriate for the piggyback actuator in a magnetic head, for example.

The driving apparatus of each embodiment of the present invention is explained below with reference to the drawings.

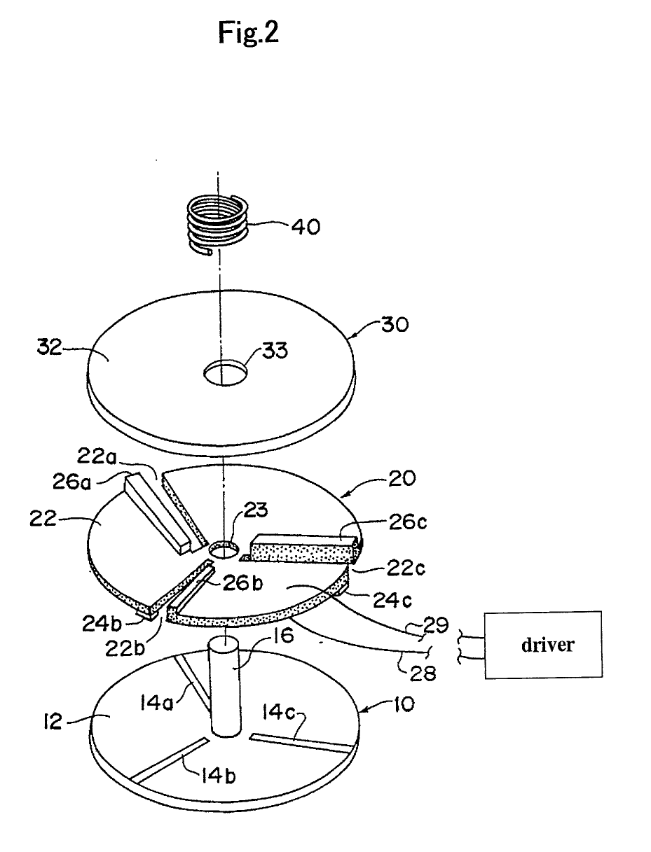

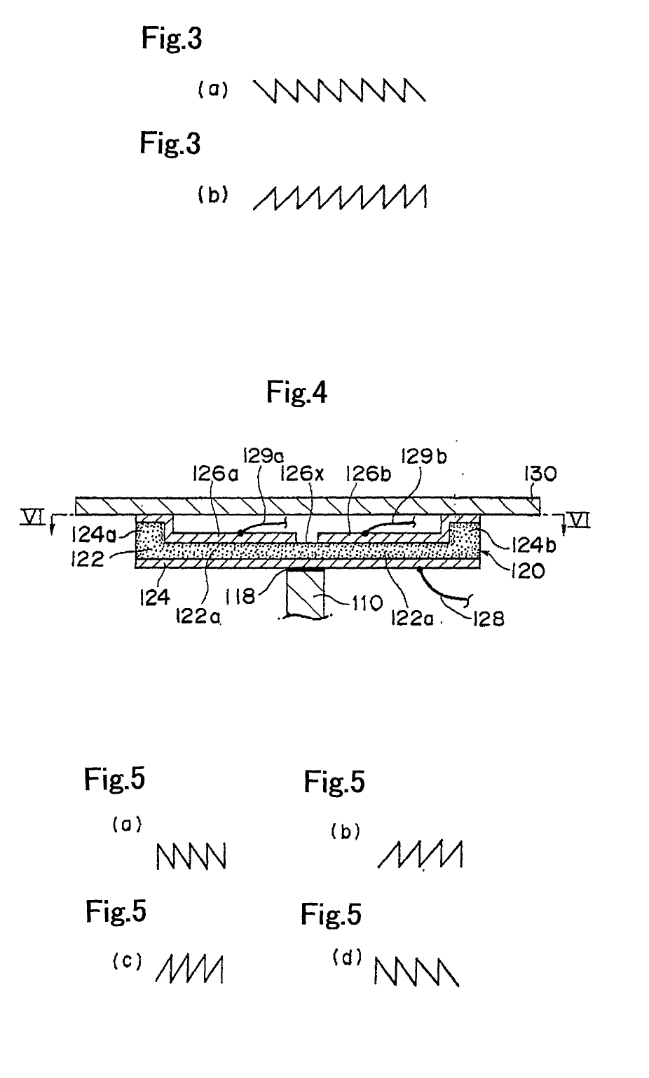

The rotary driving apparatus comprising a first embodiment of the present invention will first be explained with reference to FIGS. 2 and 3.

As shown in the perspective view of disassembled components of FIG. 2, the driving apparatus comprises a driving unit 20 that is fixed to the substrate 10 via an adhesive, and a rotor 30, which is pressed down onto the driving unit 20 by a spring 40.

The substrate 10 has a shaft 16 that protrudes from the top surface of the disk-like main unit 12.

The driving unit 20 comprises a piezoelectric material, i.e., a ceramic piezoelectric material including PZT [Pb(Zr,Ti)O₃] as an ingredient, for example. The driving unit 20 has electrodes formed on the top and bottom surfaces of the disk-like main unit 22. Lead wires 28 and 29, which may be connected to a driver, are electrically connected to the electrodes, respectively. A hole 23 is formed in the center of the main unit 22 such that the shaft 16 of the substrate 10 may be inserted therein. In the main unit 22 three notches 22a, 22b, 22c are formed that extend radially. On the top surface of the main unit 22 protrusions 26a, 26b and 26c are formed along one side of each notch 22a, 22b and 22c, respectively. The protrusions (any of the protrusions disclosed herein) may be, for example, plated by nickel, phosphorous bronze or diamond like carbon to prevent wearing of electro-mechanical transducers. Hence, the amount of movement can increase despite thin electro-mechanical transducers.

On the bottom surface of the main unit 22 adhesion units 24a (not shown in the drawing), 24b and 24c are formed along the other side of each notch 22a, 22b and 22c, respectively. The shaft 16 of the substrate 10 is inserted in the hole 23 of the main unit 22 of the driving unit 20 such that the driving unit 20 is placed on the substrate 10. The adhesion units 24a (not shown in the drawing), 24b and 24c are glued and fixed to adhesion units 14a, 14b and 14c, respectively, which are radially located on the top surface of the substrate 10.

At the center of the disk-like main unit 32 of the rotor 30 is a hole 33 in which the shaft 16 of the substrate 10 is inserted, such that the rotor 30 may rotate around the shaft 16. The rotor 30 is pressed onto the driving unit 20 by the spring 40, such that the bottom surface of the rotor 30 is frictionally engaged with the protrusions 26a, 26b and 26c of the driving unit 20. The bottom surface of the rotor 30 and the top surfaces of the protrusions 26a, 26b and 26c, which are frictionally engaged with each other, have a surface roughness having a minimum prescribed value to ensure stable frictional engagement.

In order to drive the rotor 30 to rotate, a voltage is applied between the electrodes of the driving unit 20 via the lead wires 28 and 29. Through this application of voltage, the main unit 22 of driving unit 20 extends and contracts in either direction perpendicular to the direction of voltage application, i.e., along the surface, which is perpendicular to the thickness. Because the main unit 22 is divided into three sections by the notches 22a, 22b and 22c (such that it can easily extend and contract in either direction in which the circumference extends), and because each section is glued and fixed to the substrate 10 via the adhesion units 24a (not shown in the drawing), 24b and 24c (each of which is located on one side of each section), when a voltage is applied, the protrusions 26a, 26b and 26c on the other side of each section move along the circumference. For example, if a sawtooth voltage shown in FIG. 3(a) or 3(b) is applied between the electrodes of the driving unit 20, the protrusions 26a, 26b and 26c move relatively slowly in a first direction along the circumference. The protrusions 26a, 26b and 26c move at a relatively high speed in a second direction opposite from the first direction along the circumference, or vice versa. Using this phenomenon, the rotor 30 may be rotated in the first direction (or the second direction) along the circumference as to which the protrusion 26a, 26b and 26c moves relatively slowly.

Because the protrusions 26a, 26b and 26c and the rotor 30 are frictionally engaged, even if slipping takes place therebetween, when the protrusions 26a, 26b and 26c move in the first direction (or the second direction) along the circumference relatively slowly (at a relatively low speed), the rotor 30 moves in the same direction as the protrusions 26a, 26b and 26c, i.e., the first direction (or the second direction) along the circumference due to the friction from the protrusions 26a, 26b and 26c. On the other hand, when the protrusions 26a, 26b and 26c move in the second direction (or the first direction) along the circumference relatively fast (at a relatively high speed), the rotor 30 continues to move in the first direction (or the second direction) due to the inertia thereof, or stops, and the protrusions 26a, 26b and 26c move in the second direction (or the first direction) along the circumference relative to the rotor 30. Through this phenomenon, the rotor 30 rotates in the first direction (or the second direction) along the circumference relative to the substrate 10 and the driving unit 20.

The linear-motion driving apparatus of a second embodiment of the present invention will now be explained with reference to FIGS. 4 through 7.

As shown in the cross-sectional view of FIG. 4, the driving apparatus comprises a driving unit 120, which is glued and fixed to a support 110 at its center, and a table 130 is placed on the driving apparatus.

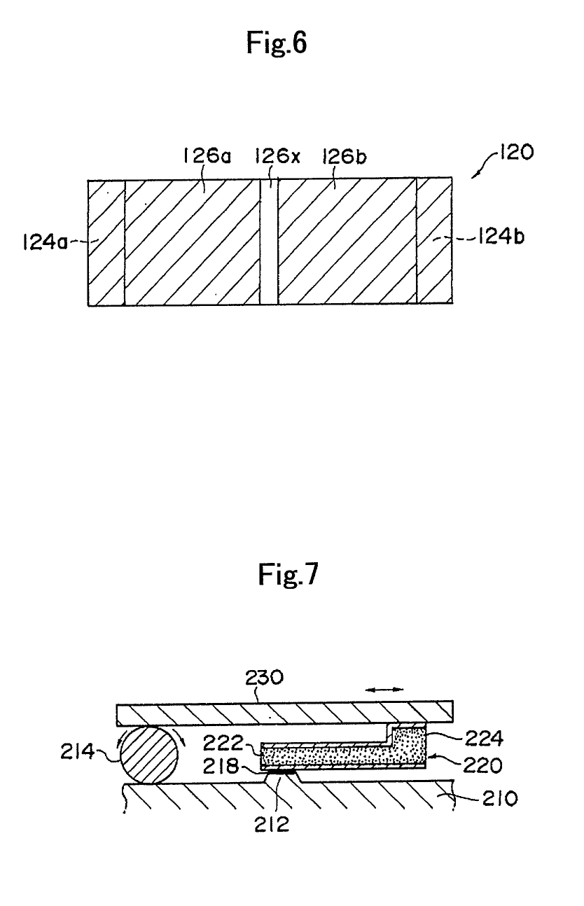

The driving unit 120 comprises a piezoelectric material, as in the case of the first embodiment, and as shown in the plan view of FIG. 6, has a long plate-like main unit 122. On either end of the top surface of the length of the main unit 122 are formed protrusions 124a and 124b that extend along the width of the main unit 122 and protrude upward. As shown in FIG. 4, an electrode 124 is formed on the entire bottom surface of the main unit 122, and the center thereof is glued and fixed to the support 110 across its width. On the top surface of the main unit 122 electrodes 126a and 126b are formed on either side of the lengthwise centerline, and a gap 126x exists between the electrodes 126a and 126b. Lead wires 128, 129a and 129b are connected to the three electrodes 124, 126a and 126b, respectively.

When the table 130 is to be driven, a voltage having the waveform shown in FIG. 5(a), for example, is applied between the electrodes 124 and 126a via the lead wires 128 and 129a, and a voltage having the waveform shown in FIG. 5(b) is applied between the electrodes 124 and 126b via the lead wires 128 and 129b. Through this application of voltage, in the main unit 120, either the first section 122a (between the electrodes 124 and 126a) or the second section 122b (between the electrodes 124 and 126b) extends at a high speed and contracts slowly, while the other section contracts at a high speed and extends slowly. Because the center of the main unit 120 is fixed to the support 110, both protrusions 124a and 124b that are frictionally engaged with the table 130 move at a high speed in one direction along the length, while moving slowly in the other direction along the length. Therefore, the table 130 is driven in one direction along the length in which the protrusions 124a and 124b move slowly.

When the target object is to be driven in the opposite direction, voltages having symmetrical waveforms across an axis parallel to the time axis regarding the waveforms (shown in the drawing) should be applied. For example, a voltage having the waveform shown in FIG. 5(c) is applied between the electrodes 124 and 126a, and a voltage having the waveform shown in FIG. 5(d) is applied between the electrodes 124 and 126b.

FIG. 7 is a modification of the second embodiment and has an alternative construction. The driving unit 220 comprises half of the driving unit 120 shown in FIG. 4. One end of the main unit 222 is glued and fixed to the support 212, and a protrusion 224 is formed on the other end. The bottom surface of the table 230 is frictionally engaged with the top surface of the protrusion 224. A cylinder 214 is located on the substrate 210 such that it may freely rotate, and this cylinder 214 supports the bottom surface of the table 230 such that the table 230 may move in a parallel fashion. It is also acceptable if the table 230 is movably supported using a different mechanism in place of the cylinder 214, such as a slide bearing.

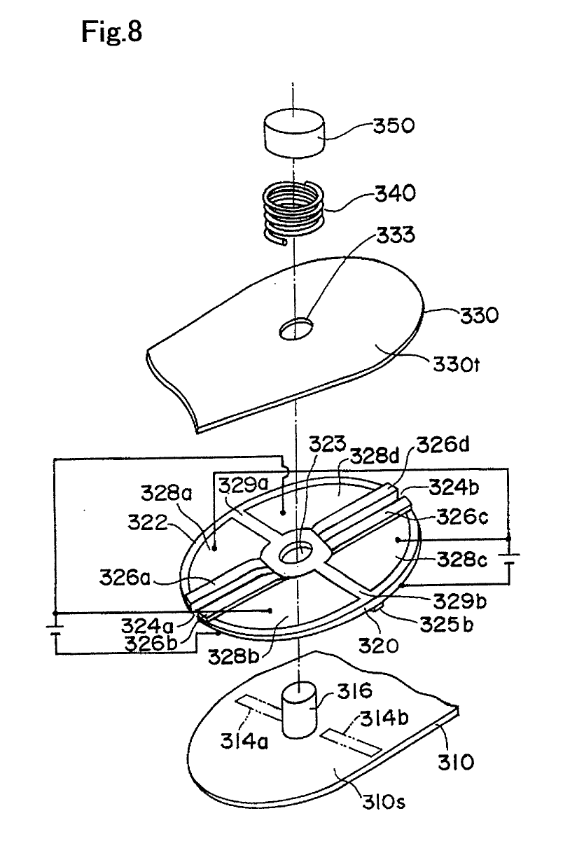

The driving apparatus of a third embodiment will now be explained with reference to FIGS. 8 through 10.

As shown in the perspective view of the components in a disassembled fashion, the driving apparatus comprises a driving unit 320, which is glued and fixed to the front end 310s of the first arm 310, and the base end 330t of the second arm 330, which is pressed onto the driving unit 320 by a spring 340 such that they are frictionally engaged with each other.

This driving apparatus is applied in the piggyback actuator to drive the head of a magnetic disk device. In other words, as shown in FIG. 10, the driving apparatus is located between the front end 310s of the first arm 310 and the base end 330t of the second arm 330. The front end 310s of the first arm 310 moves a considerable amount along the diameter of the disk (not shown in the drawings). The second arm 330 is rotatably supported by a shaft 316, which protrudes from the front end 310s of the first arm 310, and is driven to rotate by the driving apparatus. At the front end of the second arm 330 is located a magnetic head 380 that performs reading and writing of a disk (not shown in the drawing).

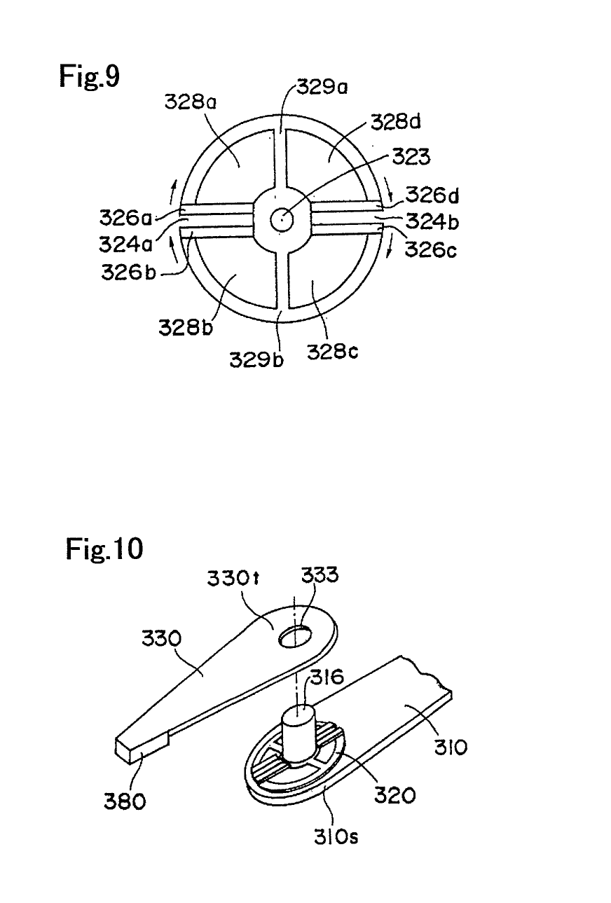

As shown in FIG. 9, the driving unit 320 includes a disk-like main unit 322 comprising a piezoelectric material, at the center of which is formed a hole 323 through which the shaft 316 of the first arm 310 is inserted. The main unit 322 has two notches 324a and 324b that extend along the diameter thereof. On the top surface of the main unit 322 protrusions 326a, 326b, 326c and 326d are formed, which are located on either side of each notch 324a and 324b, respectively, such that they protrude upward. On the bottom surface of the main unit 322 adhesion units 325a (not shown in the drawings) and 325b are formed, such that they extend perpendicular to the notches 324a and 324b, as shown in FIG. 8. The driving unit 320 is placed on the first arm 310 with the shaft 316 inserted in the hole 323 of the driving unit 320. The adhesion units 325a (not shown in the drawings) and 325b, and the adhesion units 314a and 314b on the top surface of the first arm 310, are glued and fixed together.

On the top surface of the main unit 322 electrodes 328a, 328b, 328c and 328d are formed in the four sections divided by the notches 324a and 324b and the adhesion units 325a (not shown in the drawings) and 325b, respectively. A single electrode is formed on the bottom surface of the main unit 322.

On the base end 330t of the second arm 330 a hole 333 is formed, in which the shaft 316 of the first arm 310 is inserted, and the second arm 330 is placed such that it may rotate around the shaft 316. The second arm 330 is pressed down onto the driving unit 320 by the bottom end of the spring 340. The top end of the spring 340 is pressed with a cap 350, and is fixed to the shaft 316 such that the bottom surface of the second arm 330 is frictionally engaged with the protrusions 326a, 326b, 326c and 326d of the driving unit 320.

In order to drive the second arm 330 to rotate, a voltage is applied between the electrode on the bottom surface of the driving unit 320 and each electrode 328a, 328b, 328c and 328d on the top surface. For example, a voltage having the sawtooth waveform shown in FIG. 5(a) is applied between the electrodes 328a and 328c, out of the mutually adjacent electrodes 328a, 328b, 328c and 328d, and the electrode on the bottom surface of the driving unit 320. A voltage having the opposite sawtooth waveform shown in FIG. 5(b) is applied between the electrodes 328b and 328d and the electrode on the bottom surface of the driving unit 320, on the other hand. Through this application of voltages, the portion of the main unit 322 of the driving unit 320 between the electrode on the bottom surface of the driving unit 320 and the electrodes 328a, 328b, 328c and 328d on the top surface thereof extends and contracts in either direction perpendicular to the direction of voltage application, i.e., along the surface, which is perpendicular to the thickness. Because the main unit 322 has notches 324a and 324b that extend along the diameter thereof, and is glued to the first arm 310 using the adhesion units that extend perpendicular to the notches 324a and 324b, the protrusions 326a, 326b, 326c and 326d move relatively slowly in one direction along the circumference of the main unit while they move at a relatively high speed in the opposite direction through the application of voltages. Through these movements, the second arm 330 may be rotated in one direction along the circumference of the main unit.

As explained above, because the driving apparatus of each above embodiment does not include any members between the piezoelectric element and the target object that are used to drive the target object, such as a driving shaft, the driving apparatus may be further reduced in size, thickness and cost.

The present invention is not limited to the above embodiments, and may be implemented in various other forms.

For example, if the fixing part and the frictional engagement part of the piezoelectric element are separated from each other, the target object may not be moved in a precisely straight line. In that case, a guide may be installed for the piezoelectric element or the target object, but care must be taken to ensure that the friction from the guide does not adversely affect the driving.

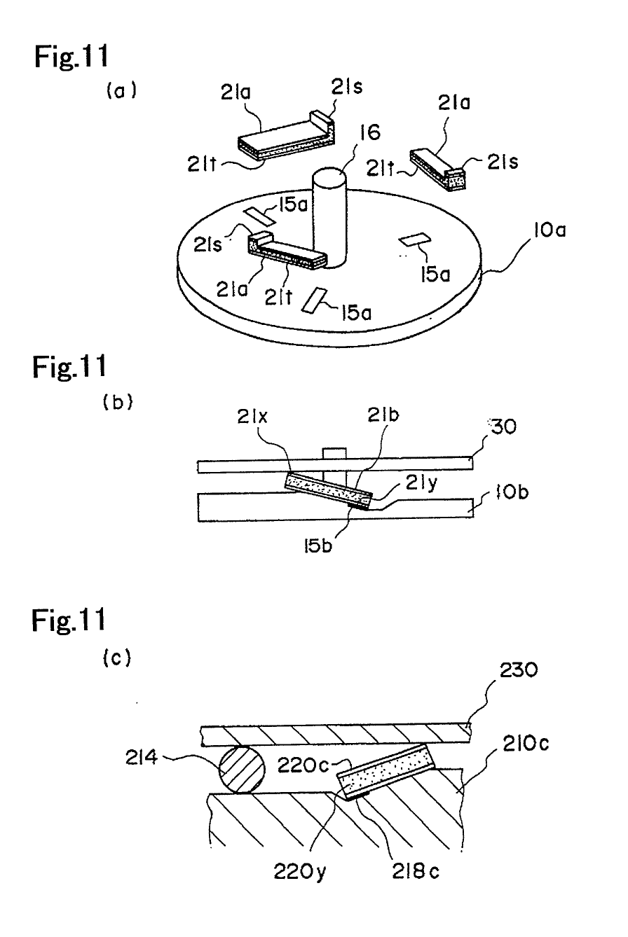

For example, in place of the driving unit 20 of FIG. 2, three piezoelectric elements 21a, each of which has a protrusion 21s and a substantially rectangular configuration, may be placed on the substrate 10a, as shown in FIG. 11(a). The bottom surfaces 21t of the piezoelectric elements 21a, not including the protrusions 21S, are glued to the substrate 10a, such that the piezoelectric elements 21a may extend and contract using the adhesion units 15a as the starting points. The protrusions 21s are frictionally engaged with the rotor 30. Because this construction does not require the member 20 that has notches and protrusions, manufacturing is easy.

Further, it is also acceptable if the piezoelectric elements 21b are located such that they are angled relative to the substrate 10b, as shown in FIG. 11(b), and one end 21x of each piezoelectric element 21b, which is higher than the other end, may be frictionally engaged with the rotor 30. The lower end 21y of each piezoelectric element 21b is glued to the substrate 10b, so that the piezoelectric elements 21b may extend and contract from the adhesion units 15b. Because the configuration of the piezoelectric element 21b is further simplified in this construction, manufacturing is made even easier.

Similarly, while a driving unit 220 that has a protrusion is used in FIG. 7, if a piezoelectric element 220c is located such that it is angled relative to the substrate, as shown in FIG. 11(c), any protrusions may be removed from the driving unit. The lower end 220y of the piezoelectric element 220c is glued to the substrate 210c, such that the piezoelectric element 220c may extend and contract from the adhesion unit 218c.

In addition, the driving unit 220 is glued and fixed to the support 212 of the substrate 210 in FIG. 7, but the driving unit 220 may be directly glued and fixed to the flat portion of the substrate 210. When the target object was moved while only one end of the driving unit was glued and fixed and the other area of the bottom part thereof was maintained in contact with the substrate, the movement was smooth. Because the driving unit and substrate have simpler configurations in this construction, manufacturing is easy.

Although the present invention has been fully described by way of examples with reference to the accompanying drawings, it is to be noted that various changes and modifications will be apparent to those skilled in the art. Therefore, unless such changes and modification depart from the scope of the present invention, they should be construed as being included therein.

What is claimed is:

1. A driving apparatus, comprising:
a base frame;
an electro-mechanical transducer one end of which is fixed to the base frame;
a moving member frictionally coupled with the electro-mechanical transducer; and
a driver to drive the electro-mechanical transducer,
wherein the driver applies a voltage such that the speed of extension of the electro-mechanical transducer between the ends thereof differs from the speed of contraction.

2. The driving apparatus of claim 1, wherein the electro-mechanical transducer has a thin plate configuration.

3. The driving apparatus of claim 2, wherein the driver applies a voltage such that the speed of extension and contraction of the electro-mechanical transducer in the direction perpendicular to polarization are different.

4. The driving apparatus of claim 2, wherein the electro-mechanical transducer has a protrusion frictionally contacted with the moving member.

5. The driving apparatus of claim 4, wherein the protrusion area is plated by material to prevent wearing of the electro-mechanical transducer.

6. The driving apparatus of claim 2, wherein the driver applies a voltage in the thickness direction of the thin plate.

7. The driving apparatus of claim 2, wherein the electro-mechanical transducer has a disk configuration and a notch.

8. The driving apparatus of claim 1, wherein the electro-mechanical transducer has a disk configuration and a protrusion frictionally contacted with the moving member, the moving member driven to rotate by applying the voltage.

9. The driving apparatus of claim 8, wherein the electro-mechanical transducer has a notch near the protrusion.

10. The driving apparatus of claim 1, wherein electro-mechanical transducer is a piezoelectric element.

11. The driving apparatus of claim 2, further comprising:
two groups of active electrodes on the thin plate,
wherein the driver applies a voltage such that a first section of the thin plate, covered by the first electrode, extends at a high speed and contracts slowly while the second section of the thin plate, covered by the second electrode, contracts at a high speed and extends slowly.

12. The driving apparatus of claim 11, wherein the electro-mechanical transducer has a disk configuration and a notch.

13. The driving apparatus of claim 12, wherein four electrodes are allocated such that surface of disk is equally divided into parts by the four electrodes, such that electrodes of diagonal position make a pair.

14. A driving apparatus, comprising:
a base frame;
an electro-mechanical transducer one end of which is fixed to the base frame, the electro-mechanical transducer has a disk configuration and a contact part;
a moving member frictionally contacted with a contact part of the electro-mechanical transducer, the moving member driven to rotate by applying a voltage; and
a driver to drive the electro-mechanical transducer,
wherein the driver applies the voltage such that a speed of extension of the electro-mechanical transducer between the ends thereof differs from the speed of contraction.

15. The driving apparatus of claim 14, wherein the electro-mechanical transducer has a notch near the contact part.

16. The driving apparatus of claim 14, further comprising:
two groups of active electrodes on a thin plate,
wherein the driver applies a voltage such that a first section of the thin plate, covered by the first electrode, extends at a high speed and contracts slowly while the second section of the thin plate, covered by the second electrode, contracts at a high speed and extends slowly.

17. The driving apparatus of claim 16, wherein four electrodes are allocated such that surface of disk is equally divided into parts by the four electrodes, such that electrodes of diagonal position make a pair.

18. The driving apparatus according to claim 14, wherein the driver applies a voltage such that speeds of extension and contraction of the electro-mechanical transducer in the direction perpendicular to polarization are different.

19. The driving apparatus according to claim 14, wherein the contact part is plated by material to prevent wearing of the electro-mechanical transducer.

20. The driving apparatus, comprising:
a base frame;
an electro-mechanical transducer one end of which is fixed to the base frame, the electro-mechanical transducer has a thin plate configuration and a contact part;
a moving member frictionally contacted with the contact part of the electro-mechanical transducer; and
a driver to drive the electro-mechanical transducer,
wherein the driver applies a voltage such that a speed of extension of the electro-mechanical transducer between the ends thereof differs from the speed of contraction.

21. The driving apparatus according to claim 20, further comprising:
two groups of active electrodes on a thin plate,
wherein the driver applies a voltage such that a first section of the thin plate, covered by the first electrode, extends at a high speed and contracts slowly while the second section of the thin plate, covered by the second electrode, contracts at a high speed and extends slowly.

22. The driving apparatus according to claim 20, wherein the driver applies a voltage such that speeds of extension and contraction of the electro-mechanical transducer in the direction perpendicular to polarization are different.

23. The driving apparatus according to claim 20, wherein the contact part is plated by material to prevent wearing of the electro-mechanical transducer.

24. A method of driving an electro-mechanical transducer having two sections covered by two active electrodes, comprising:
applying a voltage such that a first section of the electro-mechanical transducer extends at a high speed while a second section of the electro-mechanical transducer contracts slowly; and
applying the voltage such that the first section of the electro-mechanical transducer contracts slowly while the second section of the electro-mechanical transducer extends at a high speed.

25. The method of driving the electro-mechanical transducer of claim 24, wherein the electro-mechanical transducer has a disk configuration, and a moving member is driven to rotate by applying the voltage.
